(19) United States
(12) Patent Application Publication
(10) Pub. No.: US 2018/0240810 A1
(43) Pub. Date: Aug. 23, 2018

(54) SEMICONDUCTOR MEMORY DEVICE AND MANUFACTURING METHOD OF SEMICONDUCTOR MEMORY DEVICE

(71) Applicant: Toshiba Memory Corporation, Minato-ku (JP)

(72) Inventor: Muneyuki Tsuda, Ichinomiya (JP)

(73) Assignee: Toshiba Memory Corporation, Minato-ku (JP)

(21) Appl. No.: 15/824,136

(22) Filed: Nov. 28, 2017

(30) Foreign Application Priority Data
Feb. 23, 2017 (JP) 2017-032178

(51) Int. Cl. H01L 27/11582; H01L 29/51; H01L 29/66; H01L 21/311

(52) U.S. Cl. CPC H01L 27/11582; H01L 21/31111; H01L 29/66833; H01L 29/517

(57) ABSTRACT

According to an embodiment, a semiconductor memory device includes a pillar member, a plurality of insulating layers arranged on an outer peripheral surface of the pillar member, an electrode film arranged between the insulating layers adjacent in a height direction, and a second block insulating film arranged between the electrode film and the pillar member and between the electrode film and the insulating layers. The pillar member includes a first block insulating film, a memory film, and a channel semiconductor layer in order from a side at its outer peripheral surface. The first block insulating film and the second block insulating film are made of an insulating material having a relative dielectric constant larger than that of silicon oxide. A distance between the memory film and the electrode film is a sum of a thickness of the first block insulating film and a thickness of the second block insulating film. The thickness of the second block insulating film is equal to or larger than the thickness of the first block insulating film, and is twice or less the thickness of the first block insulating film.

### CROSS-REFERENCE TO RELATED APPLICATIONS

This application is based upon and claims the benefit of priority front Japanese Patent Application No. 2017-032178, filed on Feb. 23, 2017; the entire contents of which are incorporated herein by reference.

### FIELD

An embodiment described herein relates generally to a semiconductor memory device and a manufacturing method of a semiconductor memory device.

### BACKGROUND

In recent years, along with the progress of scaling of semiconductor memory devices, a three-dimensional device has been proposed which includes memory cells with a stacked structure. In the three-dimensional device, structure bodies are arranged in a two-dimensional state on a silicon layer, where each structure body includes a plurality of memory cells stacked in the height direction.

Manufacturing of the three-dimensional device involves many processes, such as film formation and etching, and so the completed three-dimensional device may suffer variations in film thickness or the like. Such variations in film thickness or the like in the three-dimensional device deteriorate the writing characteristic or erasing characteristic of memory cells in some cases.

### BRIEF DESCRIPTION OF THE DRAWINGS

FIG. 1 is a perspective view schematically illustrating a structural example of a semiconductor memory device;

FIG. 2 is a sectional view schematically illustrating a configuration example, in a direction perpendicular to a Z-direction, of a memory cell part in a semiconductor memory device according to an embodiment;

FIG. 3 is a sectional view schematically illustrating a configuration example, in a direction perpendicular to an X-direction, of the memory cell part in the semiconductor memory device according to the embodiment;

FIG. 4 is an enlarged sectional view partly illustrating the memory cell part in the semiconductor memory device according to the embodiment;

FIGS. 5A to 5F are sectional views schematically illustrating structural examples of memory cells according to the embodiment and comparative examples;

FIG. 6 is a diagram illustrating the writing characteristic and erasing characteristic of the memory cells according to the embodiment and comparative examples, which are illustrated in FIGS. 5A to 5F;

FIGS. 7A to 7F are sectional views schematically illustrating an example of the process sequence of a manufacturing method of the semiconductor memory device according to the embodiment;

FIGS. 8A and 8B are sectional views illustrating steps for forming each pillar member;

FIGS. 9A to 9C are sectional views illustrating steps for forming each electrode film; and

FIGS. 10A to 10D are sectional views schematically illustrating an example of the sequence of a manufacturing method of a semiconductor memory device according to the comparative example 1.

### DETAILED DESCRIPTION

In general, according to one embodiment, a semiconductor memory device includes a pillar member arranged above a semiconductor layer, a plurality of insulating layers arranged on an outer peripheral surface of the pillar member, along a height direction of the pillar member, an electrode film arranged between the insulating layers adjacent in the height direction, and a second block insulating film arranged between the electrode film and the pillar member and between the electrode film and the insulating layers. The pillar member includes a first block insulating film, a memory film, and a channel semiconductor layer in order from a side at its outer peripheral surface. The first block insulating film and the second block insulating film are made of an insulating material having a relative dielectric constant larger than that of silicon oxide. A distance between the memory film and the electrode film is a sum of a thickness of the first block insulating film and a thickness of the second block insulating film. The thickness of the second block insulating film is equal to or larger than the thickness of the first block insulating film, and is twice or less the thickness of the first block insulating film.

An exemplary embodiment of a semiconductor memory device and a manufacturing method of a semiconductor memory device will be explained below in detail with reference to the accompanying drawings. The present invention is not limited to the following embodiment. The sectional views of a semiconductor memory device used in the following embodiment are schematic, and so the relationship between the thickness and width of each layer and/or the thickness ratios between respective layers may be different from actual states. Further, the film thicknesses shown hereinafter are mere examples, and they are not limiting.

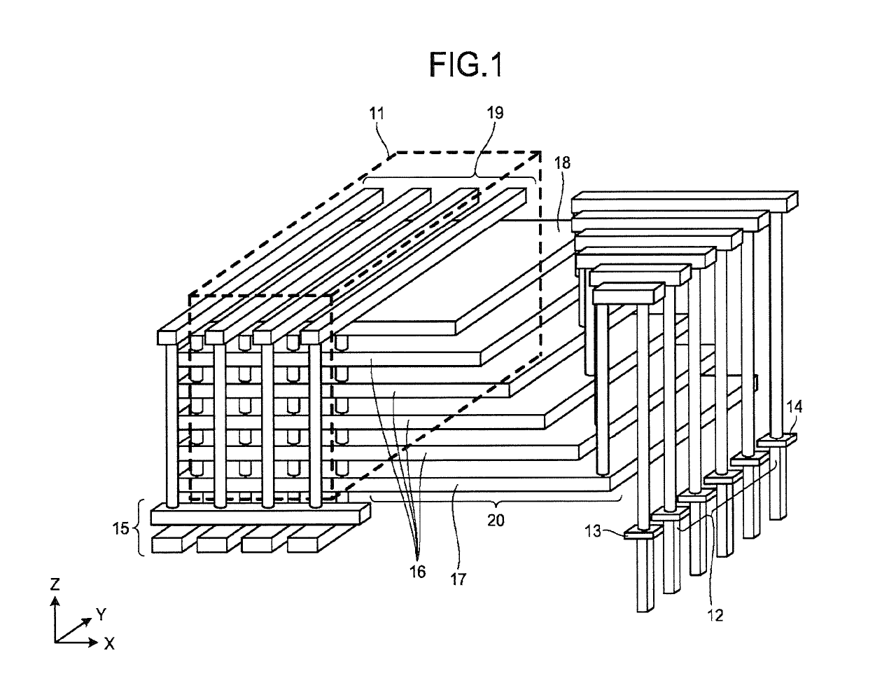

FIG. 1 is a perspective view schematically illustrating a structural example of a semiconductor memory device. The semiconductor memory device includes a memory cell part 11, a word line drive circuit 12, a source-side selection gate line drive circuit 13, a drain-side selection gate line drive circuit 14, a sense amplifier 15, word lines 16, a source-side selection gate line 17, a drain-side selection gate line 18, and bit lines 19. Hereinafter, it is assumed that the extending direction of the bit lines 19 is a Y-direction, the stacked direction of memory cell transistors is a Z-direction, and a direction perpendicular to the Y-direction and the Z-direction is an X-direction.

The memory cell part 11 has a configuration in which a plurality of memory strings are arranged on a substrate, where each memory string includes a memory cell column composed of one or more memory cell transistors (each of which will also be simply referred to as “memory cell”, hereinafter) arrayed in the direction, together with a drain-side selection transistor and a source-side selection transistor respectively provided at the upper and lower ends of the memory cell column. As described later, each of the memory cell transistors, the drain-side selection transistor, and the source-side selection transistor has a structure in which a gate electrode is arranged on a side surface of a cylindrical structure body including a semiconductor film, a tunnel insulating film, a charge accumulation layer, and a block insulating film stacked in this order. In each memory cell transistor, the gate electrode serves as a control gate electrode, and, in each of the drain-side selection transistor and the source-side selection transistor, the gate electrode serves as a selection gate electrode. The example illustrated here is a case where one memory string is provided with memory cells in four layers.

Each word line 16 connects the control gate electrodes of memory cells at the same height to each other among memory strings present within a predetermined range. Further, the source-side selection gate line 17 connects the selection gate electrodes of source-side selection transistors to each other among the memory strings present within the predetermined range. The drain-side selection gate line 18 connects the selection gate electrodes of drain-side selection transistors to each other among the memory strings present within the predetermined range. Further, the bit lines 19 are arranged such that they are connected to the upper sides of the respective memory strings in a direction intersecting with the X-direction (here, in the Y-direction perpendicular to the X-direction).

The word line drive circuit 12 is a circuit for controlling voltage to be applied to the word lines 16. The source-side selection gate line drive circuit 13 is a circuit for controlling voltage to be applied to the source-side selection gate line 17. The drain-side selection gate line drive circuit 14 is a circuit for controlling voltage to be applied to the drain-side selection gate line 18. Further, the sense amplifier 15 is a circuit for amplifying an electric potential read from a selected memory cell. Here, in the following description, when there is no need to distinguish the source-side selection gate line 17 and the drain-side selection gate line 18 from each other, they will be simply referred to as “selection gate line”. Further, when there is no need to distinguish the source-side selection transistor and the drain-side selection transistor from each other, they will be simply referred to as “selection transistor”.

The word lines 16 and the selection gate lines 17 and 18 of the memory cell part 11 are connected to the word line drive circuit 12, the source-side selection gate line drive circuit 13, and the drain-side selection gate line drive circuit 14, through respective contacts in a word line contact part 20 (electrode line contact part) provided for the memory cell part 11. The word line contact part 20 is arranged on that side of the memory cell part 11 which faces the word line drive circuit 12, and is structured such that the word lines 16 and the selection gate lines 17 and 18, which are connected to the memory cells and the selection transistors present at respective heights, have been processed in a stepwise state.

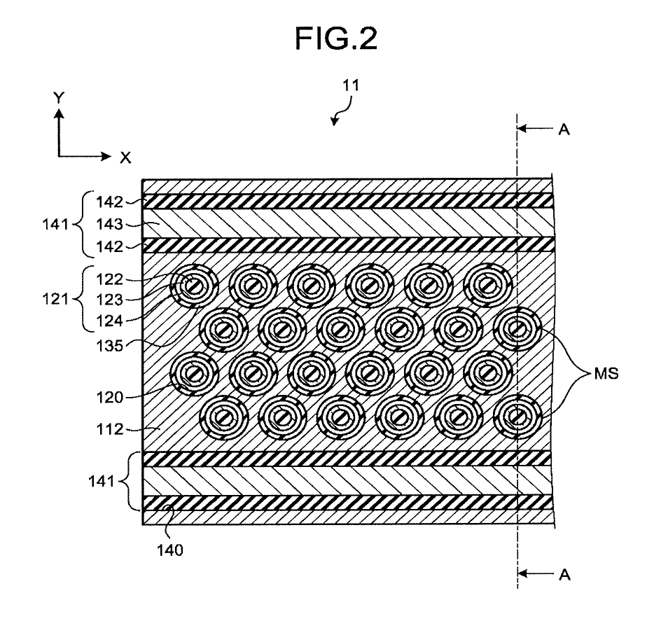

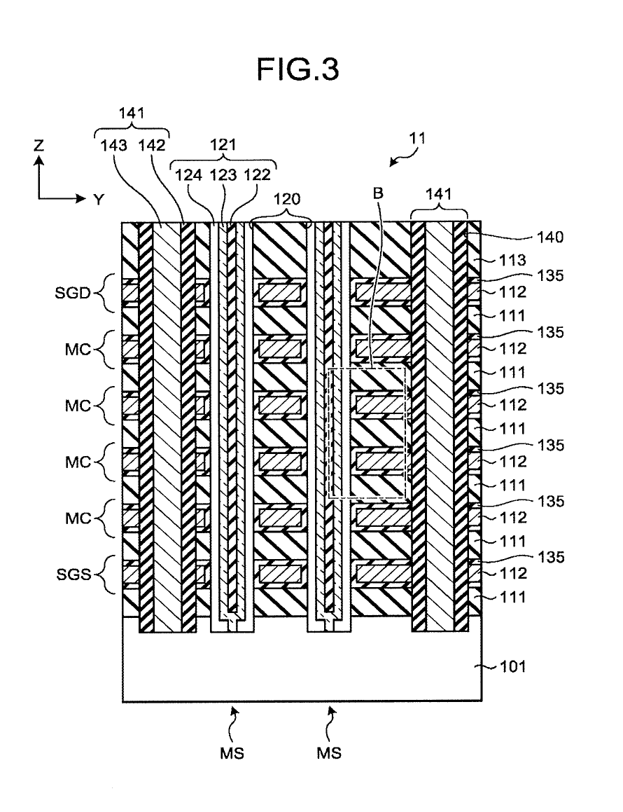

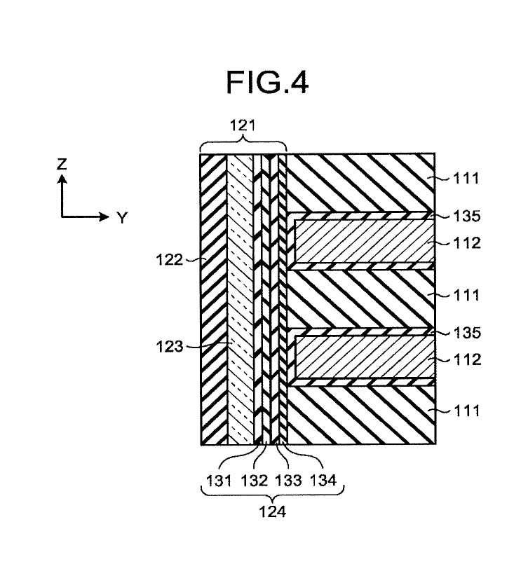

FIG. 2 is a sectional view schematically illustrating a configuration example, in a direction perpendicular to the Z-direction, of the memory cell part in a semiconductor memory device according to an embodiment. FIG. 3 is a sectional view schematically illustrating a configuration example, in a direction perpendicular to the X-direction, of the memory cell part in the semiconductor memory device according to the embodiment. FIG. 4 is an enlarged sectional view partly illustrating the memory cell part in the semiconductor memory device according to the embodiment. Here, FIG. 2 is a view illustrating a portion cut by a plane parallel with the substrate surface, at the position of the drain-side selection transistor, and seen from the upper side. Further, FIG. 3 corresponds to a sectional view taken along a line A-A of FIG. 2. FIG. 4 is an enlarged view of a region F of FIG. 3.

In the memory cell part 11, as illustrated in FIGS. 2 to 4, memory strings MS are arranged almost vertically and in a two-dimensional state above a semiconductor layer 101. The semiconductor layer 101 may be a semiconductor substrate, or may be a semiconductor film provided above a semiconductor substrate. Each memory string MS has a configuration in which a plurality of transistors are connected in series. Each memory string MS includes a pillar member 121, electrode films 112, and block insulating films 135.

The pillar member 121 includes a columnar core insulating layer 122, a channel semiconductor layer 123 provided on the outer peripheral surface of the columnar core insulating layer 122, and a multi-layer film 124 provided on the outer peripheral surface of the channel semiconductor layer 123. Accordingly, each of the channel semiconductor layer 123 and the multi-layer film 124 has a cylindrical shape. The core insulating layer 122 is made of, for example, an insulating material, such as silicon oxide (SiO₂). The channel semiconductor layer 123 is provided to serve as the channels of the transistors composing the memory string MS. The channel semiconductor layer 123 has a thickness of 14.5 nm, and is made of a semiconductor material, such as poly-silicon (Poly-Si), for example.

The multi-layer film 124 includes a memory film and a block insulating film 134 in this order from the channel semiconductor layer 123 side toward the electrode films 112. The memory film includes a tunnel insulating film 131, a charge accumulation layer 132, and a block insulating film 133 in this order from the channel semiconductor layer 123 side toward the electrode films 112. The tunnel insulating film 131 has a thickness of 6.5 nm, and is made of an insulating material, such as silicon oxide, for example. The charge accumulation layer 132 has a thickness of 6 nm, and is made of a material that enables charge accumulation, such as silicon nitride (SiN), for example. The block insulating film 133 has a thickness of 6 nm, and is made of an insulating material, such as silicon oxide, for example. The block insulating film 134 is made of an insulating material having a dielectric constant higher than that of the block insulating film 133. In other words, the block insulating film 134 is made of an insulating material having a relative dielectric constant higher than that of silicon oxide. The block insulating film 134 has a thickness of 3 nm, and is made of a metal oxide material, such as aluminum oxide (Al₂O₃), zirconium oxide (ZrO₂) or hafnium oxide (HfOx), for example.

The electrode films 112 are arranged in a plural number in the height direction (Z-direction) of the pillar member 121. Spacer films 111 are arranged such that each of them is interposed between electrode films 112 mutually adjacent in the Z-direction. Each spacer film 111 serves as an insulating layer for electrical isolation between electrode films 112 mutually adjacent in the Z-direction. The electrode films 112 are made of, for example, a metal material, such as tungsten (W).

The block insulating films 135 are arranged between the electrode films 112 and the block insulating film 134 and between the electrode films 112 and the spacer films 111. The block insulating films 135 are made of an insulating material having a dielectric constant higher than that of the block insulating film 133. In other words, the block insulating films 135 are made of an insulating material having a relative dielectric constant higher than that of silicon oxide. In this embodiment, each block insulating film 135 has a thickness once to twice a thickness of the block insulating film 134, and is made of a metal oxide material, such as aluminum oxide, zirconium oxide, or hafnium oxide.

Here, a barrier metal film may be provided on the outer peripheral surface of each electrode film 112, to prevent migration of elements between the electrode film 112 and the surrounding insulating films (such as the block insulating films 133 to 135 and spacer films 111). The barrier metal film is made of, for example, a metal nitride material, such as titanium nitride (TiN), tungsten nitride (WN), or tantalum nitride (TaN). Each block insulating film 135 is provided in a state covering the outer peripheral surface of the corresponding electrode film 112.

In this embodiment, where the thickness of the block insulating film 134 is t1 and the thickness of each block insulating film 135 is t2, the thickness t3 of the block insulating films 134 and 135 interposed between the electrode films 112 and the block insulating film 133 has a value expressed by the following formula (1).

t3=t1+t2 (1)

The block insulating film 134 is provided so that it can prevent the block insulating film 133 from being removed when the sacrificial films present at the positions corresponding to the electrode films 112 are removed in a manufacturing method of the semiconductor memory device, as described later. Even if the block insulating film 134 is partly etched when the sacrificial films are being removed, its effective oxide film thickness is hardly changed, because the block insulating film 134 is a high dielectric constant film (High-k film). Thus, a thickness of the block insulating film 133 is kept constant, and the effective oxide film thickness of the block insulating film 134 is kept almost constant. Consequently, it is possible to suppress variations in the characteristics of the memory cells MC.

As the block insulating films 135 high in dielectric constant are arranged at the respective positions between the spacer films 111 and the electrode films 112, it becomes difficult for electrons to be injected from the electrode films 112 intro the charge accumulation layer 132. As a result, the erasing characteristic of the memory cells MC is improved, as compared with a case where the block insulating films 135 are not arranged. In this embodiment, the block insulating films have a structure with three stacked layers.

As described above, the block insulating films 135 made of the high dielectric constant material are arranged between the electrode films 112 and the spacer films 111 mutually adjacent in the 2-direction, and the block insulating films 134 and 135 made of the high dielectric constant material are arranged between the electrode films 112 and the block insulating film 133. Consequently, it is possible to suppress variations in the effective oxide film thickness of the block insulating films 133, 134, and 135 between the electrode films 112 and the channel semiconductor layer 123 in a manufacturing process of the semiconductor memory device. This makes it possible to suppress variations in the characteristics of the memory cells MC, and to improve the erasing characteristic of the memory cells MC.

In the column of the transistors connected in series in the Z-direction, the transistors at the upper and lower ends serve as selection transistors SGS and SGD. In the example illustrated in FIG. 3, the source-side selection transistor SGS is arranged on the lower side, and the drain-side selection transistor SGD is arranged on the upper side. Between these two selection transistors SGS and SGD, one or more memory cells MC are arranged at predetermined intervals. In this example, the selection transistors SGS and SGD have a structure identical to the structure of the memory cells MC.

As illustrated in FIG. 2, the memory cell part 11 is divided into a plurality of regions by dividing portions 141 extending in the X-direction. Here, as illustrated in FIG. 3, each dividing portion 141 has a configuration such that a slit 140, which penetrates the stacked body formed of a stack of the spacer films 111 and the electrode films 112 in the thickness direction, is filled with a spacer film 142, such as a silicon oxide film, and a filling film 143. The filling film 143 may be formed of a conductive film or insulating film. Where the filling film 143 is used as a contact with respect to the semiconductor layer 101 present below the memory cell part 11, the filling film 143 is formed of a conductive film, such as tungsten (W). On the other hand, where the filling film 143 is not used as a contact, the filling film 143 is formed of an insulating film, such as a silicon oxide film or silicon nitride film. Further, in this case, the filling film 143 may be directly formed inside the slit 140 by omitting the spacer film 142.

The transistors at the same height in a region sandwiched between dividing portions 141 are connected to each other by the same one of the electrode films 112. For example, the source-side selection transistors SGS in a region sandwiched between dividing portions 141 are connected to each other by the lowermost one of the electrode films 112. The drain-side selection transistors SGD in the region sandwiched between these dividing portions 141 are connected to each other by the uppermost one of the electrode films 112. These electrode films 112 serve as selection gate lines. Further, the memory cells MC at the same height in the region sandwiched between these dividing portions 141 are connected to each other by the corresponding one of the electrode films 112. Each electrode film 112 connecting the memory cells MC serves as a word line.

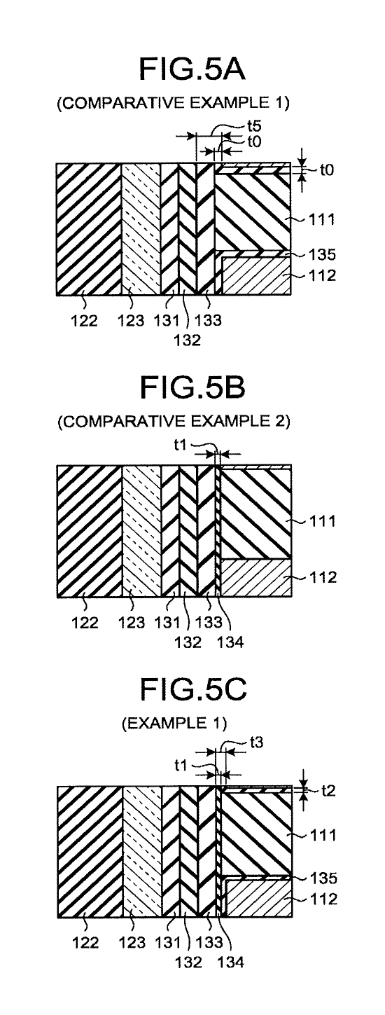

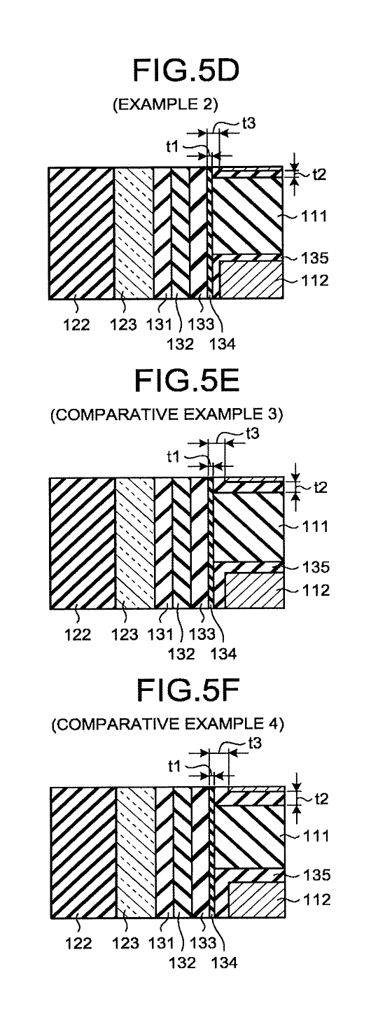

Next, an explanation will be given of the relation between the thickness of the block insulating film 134 and the thickness of each block insulating film 135 in the semiconductor memory device. FIGS. 5A to 5F are sectional views schematically illustrating structural examples of memory cells according to the embodiment and comparative examples. Here, the constituent element corresponding to those in FIGS. 2 to 4 are denoted by the same reference symbols, and their description will be omitted.

FIGS. 5A and 5B illustrate memory cell structures in a semiconductor memory device, according to comparative examples 1 and 2, respectively. In the memory cell structure illustrated by the comparative example 1, there is no block insulating film 134 provided in the pillar member 121. Here, it is assumed that the thickness of the block insulating film 133 is t5, and a thickness of the block insulating film 135 is t0. The thickness of the block insulating film 135 on the side surface, upper surface, and lower surface of the electrode film 112 is t0. In the memory cell structure illustrated by the comparative example 2, there is no block insulating film 135 provided on the outer peripheral surface of the electrode film 112. Here, the thickness of the block insulating film 134 is t1. The thickness t1 of the block insulating film 134 has a predetermined value. If the thickness of the block insulating film 134 is larger than this predetermined value, it becomes difficult to punch through the bottom of the memory hole in the manufacturing process. Accordingly, the thickness of the block insulating film 134 is set to t1, here.

FIGS. 5C and 5D illustrate memory cell structures in a semiconductor memory device, according to the embodiment. FIG. 5C illustrates a memory cell structure according to an example 1. FIG. 5D illustrates a memory cell structure according to an example 2. In the memory cell structure illustrated by the example 1, the thickness t2 of the block insulating film 135 is equal to the thickness t1 of the block insulating film 134. Thus, the example 1 satisfies the condition of the following formula (2), in addition to the formula (1).

t2=t1 (2)

Further, it is assumed that, on the side surface of the electrode film 112, the sum t1+t2 of the thicknesses of the block insulating film 134 and the block insulating film 135 is equal to the thickness t0 of the block insulating film 135 according to the comparative example 1.

In the memory cell structure illustrated by the example 2, the thickness t2 of the block insulating film 135 has a value twice the thickness t1 of the block insulating film 134. Thus, the example 2 satisfies the condition of the following formula (3), in addition to the formula (1).

t2=2t1 (3)

FIGS. 5E and 5F illustrate memory cell structures in a semiconductor memory device, according to comparative examples 3 and 4. FIG. 5E illustrates a memory cell structure according to the comparative example 3. FIG. 5F illustrates a memory cell structure according to the comparative example 4. In the memory cell structure illustrated by the comparative example 3, the thickness t2 of the block insulating film 135 has a value three times thicker than the thickness t1 of the block insulating film 134. Thus, the comparative example 3 satisfies the condition of the following formula (4), in addition to the formula (1).

t2=3t1 (4)

Further, in the memory cell structure illustrated by the comparative example 4, the thickness t2 of the block insulating film 135 has a value four times thicker than the thickness t1 of the block insulating film 134. Thus, the comparative example 4 satisfies the condition of the following formula (5), in addition to the formula (1).

t2=4t1 (5)

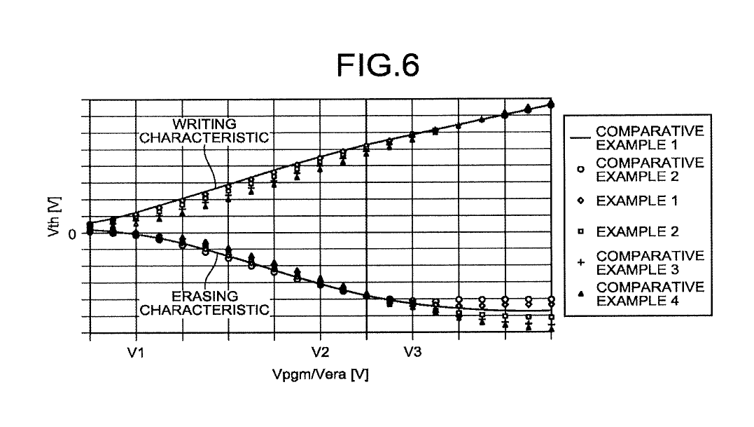

FIG. 6 is a diagram illustrating the writing characteristic and erasing characteristic of the memory cells according to the embodiment and comparative examples, which are illustrated in FIGS. 5A to 5F. In FIG. 6, the horizontal axis shows a writing voltage (Vpgm) or erasing voltage (Vera) applied to a memory cell, and the vertical axis shows the threshold voltage (fifth) of the memory cell. In the writing characteristic and the erasing characteristic, as the absolute value of the threshold voltage is larger, it indicates that the characteristics of the memory cell are better.

In the structure of the comparative example 1 where the block insulating film 135 is provided on the outer peripheral surface of the electrode film 112, when erasing is performed, the electric field is relaxed at the block insulating film 135 that is provided on the side surface of the electrode film and made of a high dielectric constant material. This makes it difficult for electrons to be injected from the electrode film 112 into the charge accumulation layer 132. However, as described later in relation to a manufacturing method of the semiconductor memory device, since no block insulating film 134 is present between the block insulating film 133 and the sacrificial film, the following can happen: When the sacrificial film is removed by wet etching, the block insulating film 133 is etched, and variations are caused in the writing characteristic and the erasing characteristic. This is because the block insulating film 133 is made of silicon oxide, which has a low relative dielectric constant, and so its film thickness difference largely affects the writing characteristic and the erasing characteristic. Hereinafter, the other examples will be compared with the result obtained by the comparative example 1, which serves as reference data.

In the comparative example 2, the block insulating film 134 is present between the block insulating film 133 and the sacrificial film. As described later in relation to the manufacturing method of the semiconductor memory device, when the sacrificial film is removed by wet etching, the block insulating film 134 made of a high dielectric constant material serves as a cover film. Consequently, the block insulating film 133 is not etched, and variations are hardly caused in the writing characteristic and the erasing characteristic. This is also because the block insulating film 134 is made of an insulating material having a relative dielectric constant higher than that of silicon oxide, and so its film thickness difference does not largely affect the writing characteristic and the erasing characteristic. Accordingly, the writing characteristic is similar to that of the comparative example 1. However, as no block insulating film 135 is provided on the outer peripheral surface of the electrode film 112, when erasing is performed, it becomes easy for electrons to be injected from the electrode film 112 into the charge accumulation layer 132. As a result, the erasing characteristic is deteriorated as compared with the comparative example 1 in the range higher than a voltage V3.

In the case of the example 1 where the film thickness of the block insulating film 135 is equal to the film thickness of the block insulating film 134, and the distance between the electrode film 112 and the charge accumulation film 132 is equal to that of the comparative example 1, the writing characteristic is almost the same as that of the comparative example 1. The erasing characteristic is almost the same as that of the comparative example 1 until the voltage V3. However, as the film thickness t2 of the block insulating film 135 in the height direction of the electrode film 112 is smaller than the film thickness t0 of the block insulating film 132 of the comparative example 1, the erasing characteristic is deteriorated to some extent as compared with the comparative example 1 in the range higher than the voltage V3. In consideration of use as a memory cell, however, the erasing characteristic is within a permissible range.

In the case of the example 2 where the film thickness of the block insulating film 135 is twice the film thickness of the block insulating film 134, the writing characteristic is almost the same as that of the comparative example 1 in the range higher than the voltage V3, but is deteriorated to some extent as compared with the comparative example 1 in the range between voltages V1 and V2. In consideration of use as a memory cell, however, the writing characteristic is within a permissible range. Further, the erasing characteristic is almost the same as that of the comparative example 1 in the range between the voltages V1 and V2, but becomes better as compared with the comparative example 1 in the range higher than the voltage V3.

As described above, each of the structures according to the examples 1 and 2 has the merits of both of the structure according to the comparative example 1 and the structure according to the comparative example 2. Specifically, when erasing is performed, the block insulating film 135, which is provided on the side surface of the electrode film 112 and made of a high dielectric constant material, serves to prevent electrons from being injected from the electrode film 112. Further, when the sacrificial film is removed in the manufacturing process of the semiconductor memory device, the block insulating film 134 serves to prevent the block insulating film 133 from being etched.

In either of the case of the comparative example 3 where the film thickness of the block insulating film 135 is three times thicker than the film thickness of the block insulating film 134, and the case of the comparative example 4 where the film thickness of the block insulating film 135 is four times thicker than the film thickness of the block insulating film 134, the erasing characteristic becomes better as compared with the comparative example 1 at the higher voltage side, but the writing characteristic and the erasing characteristic are deteriorated as compared with the comparative example 1 in the range between the voltages V1 and V2. This deterioration is in a large degree, and makes it difficult to use the comparative examples 3 and 4 in the same way as the memory cell according to the comparative example 1.

In light of the above results concerning the writing characteristic and the erasing characteristic, the film thickness t2 of the block insulating film 135 is preferably set to once or more and twice or less the film thickness t1 of the block insulating film 134.

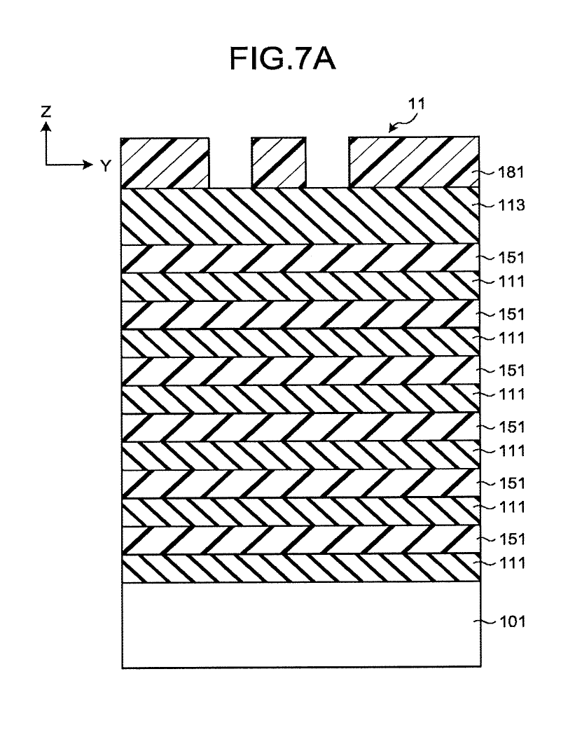

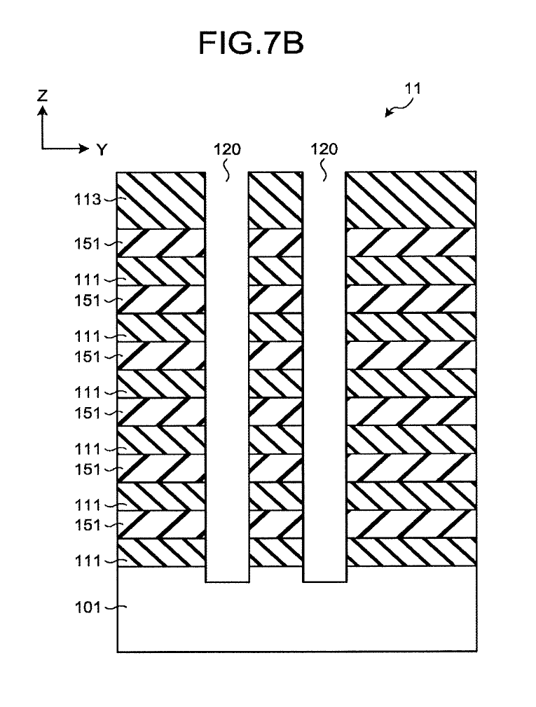

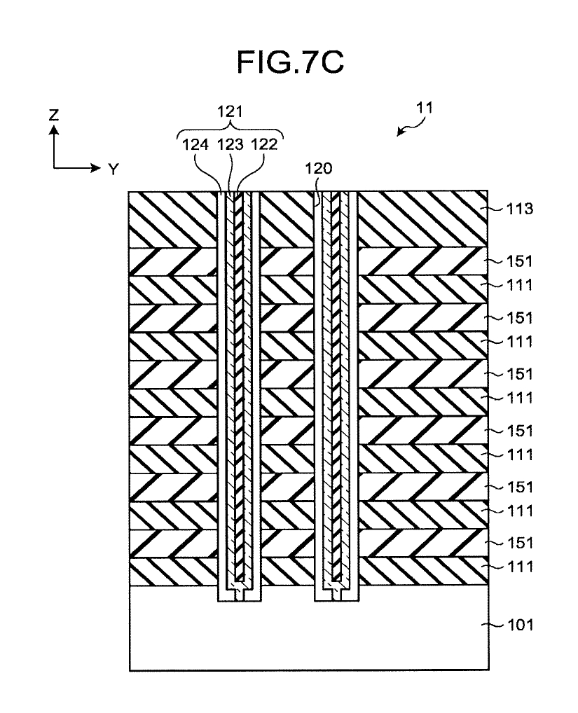

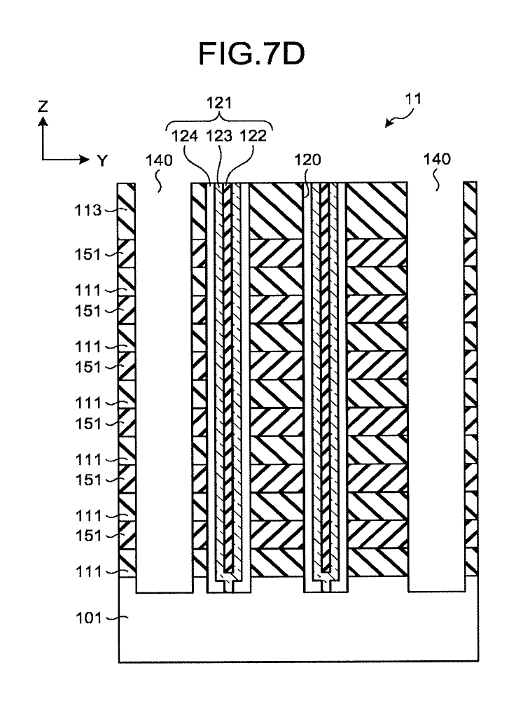

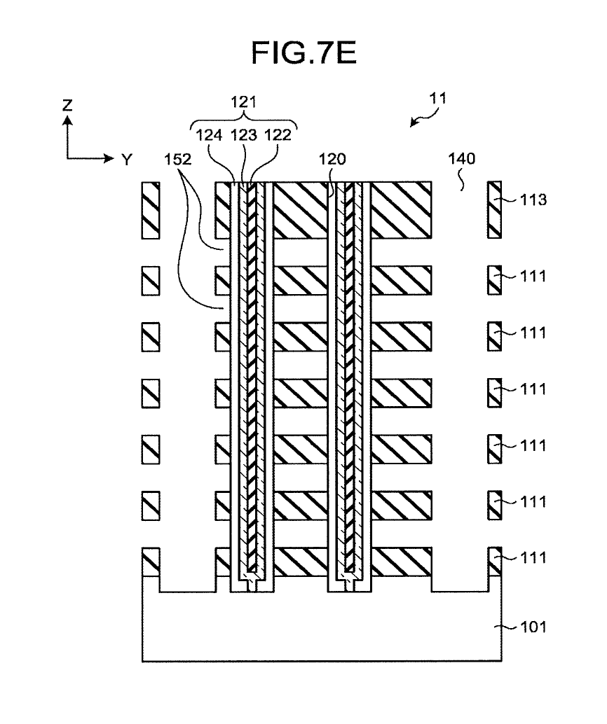

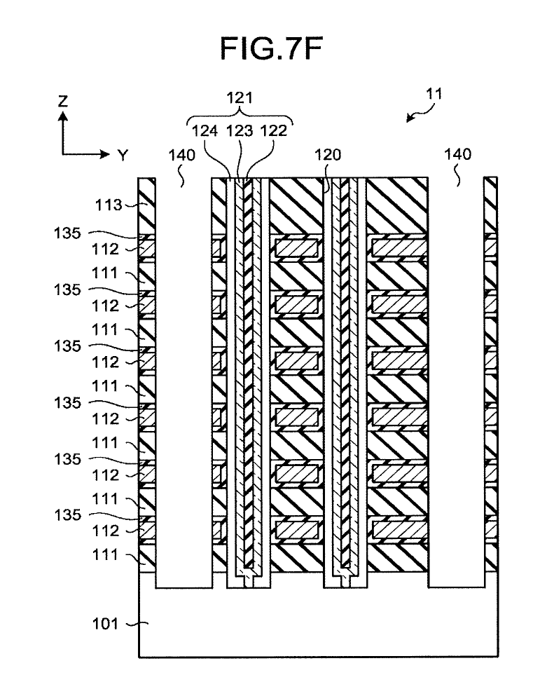

Next, an explanation will be given of a manufacturing method of a semiconductor memory device having the configuration described above. FIGS. 7A to 7F are sectional views schematically illustrating an example of the process sequence of a manufacturing method of the semiconductor memory device according to the embodiment. FIGS. 7A to 7F correspond to the sectional view of FIG. 3.

First, as illustrated in FIG. 7A, a stacked body is formed on a semiconductor layer 101 by alternately stacking a spacer film 111 and a sacrificial film 151 as a predetermined number of layers, and further stacking an insulating film 113 at the uppermost position. Further, resist is applied onto the entire surface of the stacked body. Then, a resist pattern 181 having a predetermined pattern is formed by using a lithography technique and a development technique. Here, a pattern including openings at the positions for forming pillar members 121 is formed.

As the semiconductor layer 101, for example, a silicon film may be used. As the spacer film 111, for example, a silicon oxide film may be used. As the insulating film 113, the same material as the spacer film 111 may be used, and, for example, a silicon oxide film may be used. The sacrificial film 151 is arranged at the position for forming each electrode film 112, and will be removed in a step to be performed later. Accordingly, the sacrificial film 151 is preferably made of a material that provides a selective ratio relative to the spacer film 111 when an etching process is performed. As the sacrificial film 151, for example, a silicon nitride film may be used. The thickness of each of the spacer film 111 and the sacrificial film 151 may be set to several tens of nanometers, for example.

Thereafter, as illustrated in FIG. 7B, memory holes 120 are formed by using an anisotropic etching technique, such as an Reactive Ion Etching (RIE) met d, through the resist pattern 181 serving as a mask. Each memory hole 120 is formed to penetrate the stacked body in the thickness direction. Further, the bottom of the memory hole 120 reaches down to the semiconductor layer 101.

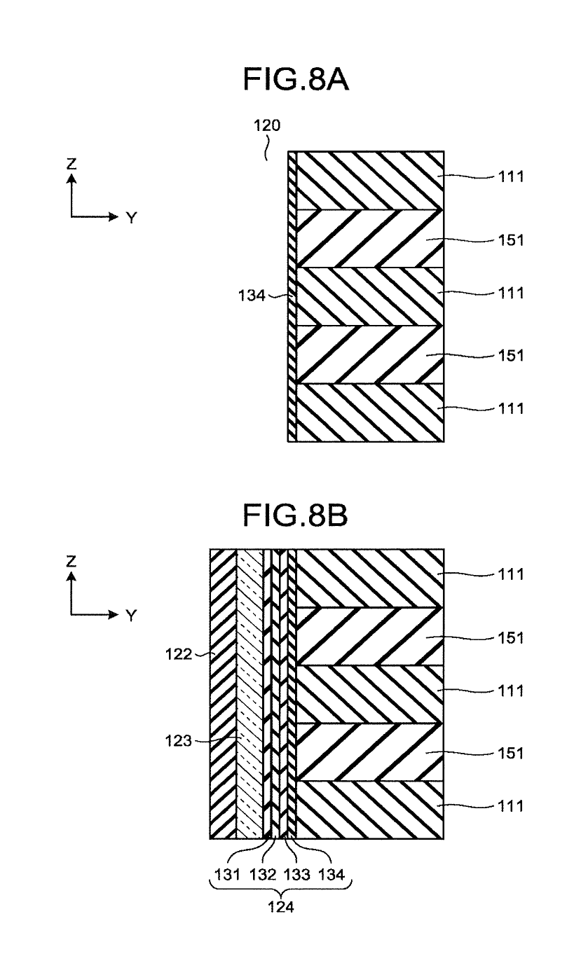

Then, as illustrated in FIG. 7C, in each memory hole 120, a pillar member 121 is formed which includes a multi-layer film 124, a channel semiconductor layer 123, and a core insulating layer 122. FIGS. 8A and 8E, are sectional views illustrating steps for forming each pillar member. FIGS. 8A and 83 correspond to a sectional view enlarging the region P of FIG. 3. As illustrated in FIG. 8A, a block insulating film 134 is formed to cover the upper surface of the insulating film 113 and the inner surface of each memory hole 120. As the block insulating film 134, for example, a high dielectric constant material film, such as an aluminum oxide film, a zirconium oxide film, or a hafnium oxide film, having a thickness of 3 nm may be used.

Then, on the inner surface of each memory hole 120 including the block insulating film 134 formed thereon, a block insulating film 133, a charge accumulation layer 132, a tunnel insulating film 131, and a cover silicon layer serving as part of a channel semiconductor layer 123 are formed in this order. As the block insulating film for example, a silicon oxide film having a thickness of 6 nm may be used. The block insulating film 133 may be formed by using a film formation method, such as a Low Pressure Chemical Vapor Deposition (LPCVD) method or an Atomic Layer Deposition (ALD) method, for example. Alternatively, the block insulating film 133 may be formed by using the following method, for example: A silicon nitride film is formed on the block insulating film 134, and, then, the silicon nitride film is oxidized by using radical oxidation, such as an in-situ Steam Generation (ISSG) oxidation process, to form the block insulating film 133. As the charge accumulation layer 132, for example, a material that enables charge accumulation, such as a silicon nitride film having a thickness of 6 nm, may be used. As the block insulating film 131, for example, a silicon oxide film having a thickness of 6.5 nm may be used. Here, the tunnel insulating film 131, the charge accumulation layer 132, and the block insulating films 133 and 134, which are stacked on the outer peripheral surface of the cover silicon layer, constitute the multi-layer film 124.

Thereafter, the cover silicon layer and the multi-layer film 124 are etched back at their portions present on the insulating film 113 and the bottom of each memory hole 120, by using anisotropic etching, such as an RIE method. Then, a channel silicon layer serving as the other part of the channel semiconductor layer 123 is formed on the cover silicon layer at the inner surface of each memory hole 120, and on an exposed portion of the semiconductor layer 101 at the bottom of the memory hole 120. The cover silicon layer and the channel silicon layer are formed each as an amorphous silicon film, for example, and are then crystallized by a heat process, so that the channel semiconductor layer 123 is formed as a poly-silicon film having a thickness of 14.5 nm, for example. Consequently, as illustrated in FIG. 8B, the multi-layer film 124 and the channel semiconductor layer 123 are formed on the side surface of each memory hole 120.

Further, a core insulating layer 122 is embedded into each memory hole 120 including the multi-layer film 124 and the channel semiconductor layer 123 formed on the side surface. As the core insulating layer 122, for example, a silicon oxide film may be used. Thereafter, the portions of the core insulating layer 122 and channel semiconductor layer 123 on the insulating film 113 are removed by using an RIE method or Chemical Mechanical Polishing (CMP) method. Consequently, the pillar member 121 is formed in each memory hole 120.

Thereafter, as illustrated in FIG. 7D, a resist (not illustrated) is applied onto the stacked body including the pillar members 121 formed in the respective memory holes 120, and a resist pattern including openings for forming slits is formed by using a lithography technique and a development technique. The openings for forming slits have shapes extending in the X-direction, and are formed on a region including the memory cell part 11 and the word line contact part 20, at predetermined intervals in the Y-direction. Then, the stacked body is etched to form slits 140 by using anisotropic etching, such as an RIE method, through the resist pattern (not illustrated) serving as a mask. Each slit 140 reaches down to the semiconductor layer 101.

Thereafter, as illustrated in FIG. 7E, the sacrificial films 151 are removed by isotropic etching. For example, the sacrificial films 151 are removed by wet etching using phosphoric acid solution (H₃PO₄), or by dry etching, such as Chemical Dry Etching (CDE). At this time, the etching is performed under conditions in which the selective ratio of the sacrificial films 151 relative to the spacer films 111 and the insulating film 113 is set to be sufficiently large.

Specifically, the etchant comes in through the slits 140 formed as described above, and etches the sacrificial film 151 on the semiconductor layer 101. Consequently, gaps 152 are formed between the spacer films 111. At this time, as the block insulating film 134 made of a high dielectric constant material is present between the block insulating film 133 formed of a silicon oxide film and the sacrificial films 151 formed of silicon nitride films to be removed, the etchant is prevented from coming into contact with the block insulating film 133 and removing the block insulating film 133. Further, even if the block insulating film 134 is etched back to some extent by the etchant in contact with the block insulating film 134, the effective oxide film thickness of the block insulating film 134 is hardly changed, because the block insulating film 134 is made of a high dielectric constant material. Consequently, the effective oxide film thickness of the block insulating films 133 and 134 is kept almost constant. In this embodiment, however, the etching is performed to the sacrificial films 151 in a manner that the block insulating film 134 is hardly removed.

As a result of the above etching, a structure is formed such that the spacer films 111 and the insulating film 113 are supported by the outer peripheral surface of each pillar member 121. Here, each pillar member 121 has a structure in which the channel semiconductor layer 123, the tunnel insulating film 131, the charge accumulation layer 132, and the block insulating films 133 and 134 are stacked on the side surface of the core insulating layer 122 that stands perpendicularly to the semiconductor layer 101.

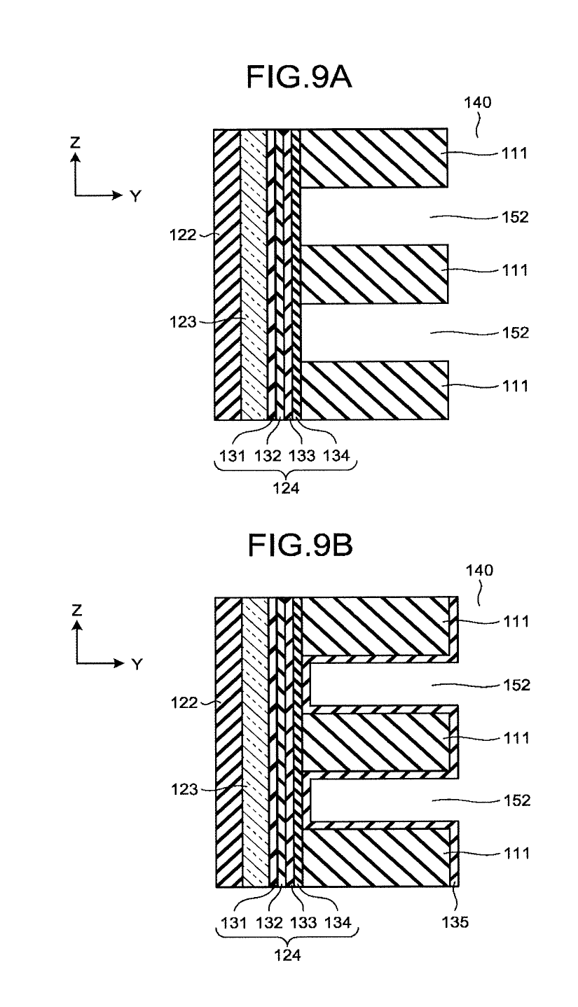

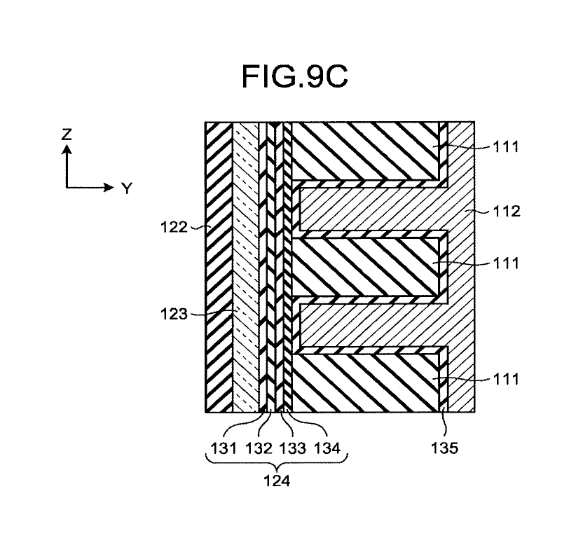

Then, as illustrated in FIG. 7F, a block insulating film 135 and an electrode film 112 are formed in each of the gaps 152 formed between the spacer films 111 adjacent in the 2-direction. FIGS. 9A to 92 are sectional views illustrating steps for forming each electrode film. FIGS. 9A to 92 correspond to a sectional view enlarging the region B of FIG. 3. From a state illustrated in FIG. 9A where the gaps 152 are formed between the spacer films 111 adjacent in the Z-direction, a block insulating film 135 is formed in a conformal state, as illustrated in FIG. 9P. As the block insulating film 135, for example, a high dielectric constant material film, such as an aluminum oxide film, a zirconium oxide film, or a hafnium oxide film, may be used. Here, where the thickness of the block insulating film 134 is 3 nm, the thickness of the block insulating film 135 may be set to 3 to 6 nm.

Thereafter, as illustrated in FIG. 9C, an electrode film 112 is formed to fill the inside of the gaps 152. As the electrode film 112, for example, tungsten or the like may be used. At this time, a barrier metal film may be formed in a conformal state on the block insulating film 135, and, thereafter, the electrode film 112 for filling is formed. As the barrier metal film, a TiN film, a WN film, or a TaN film may be used.

Then, the portions of the block insulating film 135 and electrode film 112 deposited on the side surfaces of the insulating film 113 and the spacer films 111 in the slits 140 are removed by using anisotropic etching, such as an RIE method. Further, the insulating film 113, the spacer films 111, and the electrode film 112 are etched by using anisotropic etching, such as an RIE method, to make the side surfaces of the slits 40 almost flat. Consequently, the structure illustrated in FIG. 7F is obtained.

Thereafter, a dividing portion 141 is formed in each slit 140. Specifically, a spacer film 142 is formed to cover the upper surface of the insulating film 113 and the inner surfaces of the slits 140. As the spacer film 142, for example, an insulating film, such as a silicon oxide film may be used. Thereafter, etching back is performed by using anisotropic etching, such as an RIE method, and the spacer film 142 is thereby left only on the side surfaces of each slit 140. Further, thereafter, a filling film 143 is embedded into each slit 14C. As the filling film 143, a conductive film may be used, or an insulating film may be used. Here, it is assumed that a tungsten film is embedded.

Then, the portion of the filling film 143 on the stacked body is removed by using a CMP method or the like. As a result, the semiconductor memory device illustrated in FIGS. 2 and 3 is obtained.

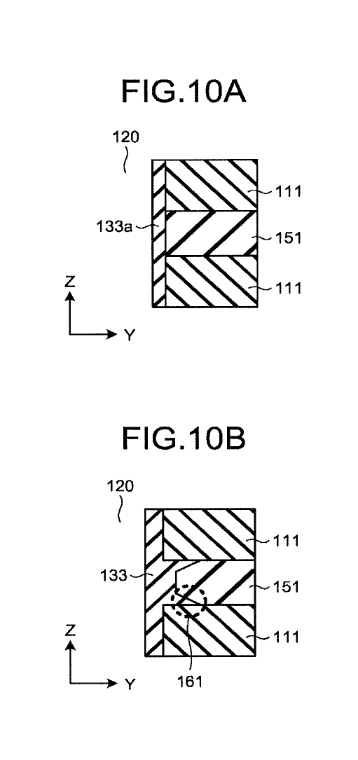

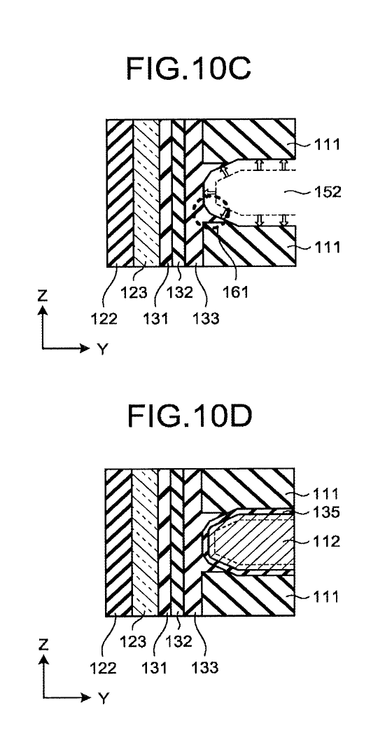

Next, an explanation will be given of an effect of this embodiment in comparison with a comparative example. FIGS. 10A to 10D are sectional views schematically illustrating an example of the sequence of a manufacturing method of a semiconductor memory device according to the comparative example 1. Here, each memory cell according to the comparative example 1 has the structure illustrated in FIG. 5A. Further, hereinafter, an explanation will be given of steps for forming each pillar member and steps for forming each electrode film.

As illustrated in FIGS. 7A and 78, memory holes 120 are formed in the stacked body, which is composed of the spacer films 111, the sacrificial films 151, and the insulating film 113. Then, as illustrated in FIG. 10A, a silicon nitride film 133a is formed in each memory hole 120.

Then, as illustrated in FIG. 10B, the silicon nitride film 133a is oxidized by radical oxidation, such as an ISSG oxidation process, and a block insulating film 133 is thereby formed. At this time, part of each sacrificial film 151 on the block insulating film 133 side is also oxidized. In the sacrificial film 151, this oxidation develops more preferentially at portions near the boundaries with the spacer films 111, as compared with its central portion in the Z-direction, and thereby forms bird's beak portions 161, as illustrated in FIG. 10B. Here, after the ISSG oxidation process, a silicon oxide film may be further formed on the upper surface of the block insulating film 133 by using an ALD method.

Thereafter, a charge accumulation layer 132, a tunnel insulating film 131, and a channel semiconductor layer 123 are formed in this order inside each memory hole 120. Here, the tunnel insulating film 131, the charge accumulation layer 132, and the block insulating film 133 correspond to a multi-layer film 124. Further, a core insulating layer 122 is embedded into each memory hole 120 including the multi-layer film 124 and the channel semiconductor layer 123 formed on the side surface.

Then, as illustrated in FIG. 7D, slits 140 are formed in the stacked body. Thereafter, as illustrated in FIG. 10C, the sacrificial films 151 are removed by wet etching using phosphoric acid solution, for example. By this isotropic etching, part of each spacer film 111 formed of a silicon oxide film is removed. Further, the respective portions from which the sacrificial films 151 have been removed become gaps 152.

Thereafter, as illustrated in FIG. 10D, a block insulating film 135 made of a high dielectric constant material is formed in a conformal state in the gaps 152, and an electrode film 112 is further formed to fill the inside of the gaps 152. Consequently, the semiconductor memory device illustrated in FIG. 5A is manufactured.

In the manufacturing method according to the comparative example 1, oxidation develops into each sacrificial film 151 from its side on which the block insulating film 133 is arranged, along the vicinities of the boundaries with the spacer films 111, and thereby forms the bird's beak portions 161. As a result, the portion of the electrode film 112 formed in each gap 152 comes to have rounded corners on the block insulating film 133 side. When this portion of the electrode film 112 has such a shape, the effective gate length becomes shorter, and the characteristics are deteriorated as compared with a case where the corners of the electrode film 112 on the block insulating film 133 side are not rounded.

On the other hand, in this embodiment, the block insulating film 134 made of a high dielectric constant material is arranged between the block insulating film 133 formed of a silicon oxide film and the stacked body composed of the spacer films 111 and the sacrificial films 151 mutually stacked as layers. Consequently, even when the block insulating film 133 is oxidized, the sacrificial films 151 can be hardly oxidized; therefore, the bird's beak portions 161 are hardly formed in each sacrificial film 151 at the end on the block insulating film 133 side. As a result, it is possible to prevent the effective gate length of each electrode film 112 from being shorter, as compared with the comparative example 1.

In the above description, each pillar member 121 has a structure including the core insulating layer 122. However, each pillar member 121 may have a structure excluding the core insulating layer 122. In this case, the channel semiconductor layer 123 comes to have a columnar structure.

According to this embodiment, the semiconductor memory device is configured such that a plurality of electrode films 112 are arranged in the height direction on the cuter peripheral surface of each pillar member 121 that stands perpendicularly to the semiconductor layer 101. In this semiconductor memory device, the block insulating film 134 made of a high dielectric constant material is arranged between the block insulating film 133 formed of a silicon oxide film and the stacked body composed of the spacer films 111 and the electrode films 112 stacked as layers. Further, the block insulating film 135 made of a high dielectric constant material is arranged around each electrode film 112. Here, it is set that, where the thickness of the block insulating film 134 is t1 and the thickness of each block insulating film 135 is t2, the thickness t3 of the block insulating films 134 and 135 interposed between the electrode films 112 and the block insulating film 133 is expressed by t1+t2, and the thickness of each block insulating film 135 satisfies t1≤t2≤2t1. Consequently, it is possible to provide a semiconductor memory device that is good in writing characteristic and erasing characteristic, while preventing the effective gate length from being shortened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a pillar member arranged above a semiconductor layer, the pillar member including a first block insulating film, a memory film, and a channel semiconductor layer in order from a side at its outer peripheral surface;
a plurality of insulating layers arranged on the outer peripheral surface of the pillar member, along a height direction of the pillar member;
an electrode film arranged between the insulating layers adjacent in the height direction; and
a second block insulating film arranged between the electrode film and the pillar member and between the electrode film and the insulating layers, wherein
the first block insulating film and the second block insulating film are made of an insulating material having a relative dielectric constant larger than that of silicon oxide,
a distance between the memory film and the electrode film is a sum of a thickness of the first block insulating film and a thickness of the second block insulating film, and
the thickness of the second block insulating film is equal to or larger than the thickness of the first block insulating film, and is twice or less the thickness of the first block insulating film.

2. The semiconductor memory device according to claim 1, wherein the memory film includes a third block insulating film, a charge accumulation layer, and a tunnel insulating film stacked in order from aside in contact with the first block insulating film.

3. The semiconductor memory device according to claim 1, wherein
the first block insulating film is an aluminum oxide film, a zirconium oxide film, or a hafnium oxide film, and
the second block insulating film is an aluminum oxide film, a zirconium oxide film, or a hafnium oxide film.

4. The semiconductor memory device according to claim 2, wherein the third block insulating film is a silicon oxide film.

5. The semiconductor memory device according to claim 1, wherein
a plurality of pillar members are arranged in a two-dimensional state above the semiconductor layer, and
the insulating layers, the electrode film, and the second block insulating film are arranged across the plurality of pillar members above the semiconductor layer.

6. The semiconductor memory device according to claim 1, wherein the pillar member further includes a columnar insulating layer having a side surface, on which the channel semiconductor layer, the memory film, and the first block insulating film are stacked in order.

7. The semiconductor memory device according to claim 1, wherein, in the pillar member, the channel semiconductor layer is cylindrical and has a side surface, on which the memory film and the first block insulating film are stacked in order.

8. The semiconductor memory device according to claim 1, further comprising a barrier metal film arranged between the electrode film and the second block insulating film.

9. A semiconductor memory device comprising:
a pillar member arranged above a semiconductor layer, the pillar member including a first block insulating film at its outer peripheral surface side;
a plurality of insulating layers arranged on a side surface of the pillar member, along a height direction of the pillar member;
an electrode film arranged between the insulating layers adjacent in the height direction; and
a second block insulating film arranged between the electrode film and the first block insulating film and between the electrode film and the insulating layers, wherein
the pillar member includes the first block insulating film, a third block insulating film, a charge accumulation layer, a tunnel insulating film, and a channel semiconductor layer in order from the outer peripheral surface side toward inside,
the first block insulating film and the second block insulating film are made of an insulating material having a relative dielectric constant larger than that of silicon oxide,
a distance between the third block insulating film and the electrode film is a sum of a thickness of the first block insulating film and a thickness of the second block insulating film, and
the thickness of the second block insulating film is equal to or larger than the thickness of the first block insulating film, and is twice or less the thickness of the first block insulating film.

10. The semiconductor memory device according to claim 9, wherein
the first block insulating film is an aluminum oxide film, a zirconium oxide film, or a hafnium oxide film, and
the second block insulating film is an aluminum oxide film, a zirconium oxide film, or a hafnium oxide film.

11. The semiconductor memory device according to claim 9, wherein the third block insulating film is a silicon oxide film.

12. The semiconductor memory device according to claim 9, wherein
a plurality of pillar members are arranged in a two-dimensional state above the semiconductor layer, and
the insulating layers, the electrode film, and the second block insulating film are arranged across the plurality of pillar members above the semiconductor layer.

13. A manufacturing method of a semiconductor memory device, the method comprising:
forming a stacked body by alternately stacking a first insulating film and a sacrificial film as a plurality of layers above a semiconductor layer;
forming a memory hole from an upper surface of the stacked body to reach down to the semiconductor layer;
forming a pillar member such that a first block insulating film, a memory film, and a channel semiconductor layer are stacked in order on a side surface inside the memory hole;
forming a plurality of slits from the upper surface of the stacked body to reach down to the semiconductor layer and to extend in a predetermined direction, after the forming a pillar member;
removing the sacrificial film through the slits;
forming a second block insulating film in a gap formed by removing the sacrificial film between layers of the first insulating film in a height direction of the pillar member; and
embedding an electrode film into the gap, wherein
the first block insulating film and the second block insulating film are made of an insulating material having a relative dielectric constant larger than that of silicon oxide,
in the removing of the sacrificial film, etching is performed under conditions not to remove the first block insulating film, and
in the forming of the second block insulating film, the second block insulating film is formed such that a thickness of the second block insulating film is equal to or larger than a thickness of the first block insulating film and is twice or less the thickness of the first block insulating film.

14. The manufacturing method of the semiconductor memory device according to claim 13, wherein, in the forming of the pillar member, as the memory film, a third block insulating film, a charge accumulation layer, and a tunnel insulating film are stacked in order on the first block insulating film.

15. The manufacturing method of the semiconductor memory device according to claim 13, wherein
the first block insulating film is an aluminum oxide film, a zirconium oxide film, or a hafnium oxide film, and
the second block insulating film is an aluminum oxide film, a zirconium oxide film, or a hafnium oxide film.

16. The manufacturing method of the semiconductor memory device according to claim 14, wherein the third block insulating film is a silicon oxide film.

17. The manufacturing method of the semiconductor memory device according to claim 14, wherein the forming of the pillar member includes
forming a silicon nitride film on the first block insulating film,
forming the third block insulating film by performing radical oxidation to the silicon nitride film, and
stacking the charge accumulation layer, the tunnel insulating film, and the channel semiconductor layer in order on the third block insulating film.

18. The manufacturing method of the semiconductor memory device according to claim 13, wherein, in the forming of the memory hole, a plurality of memory holes arranged in a two-dimensional state on the semiconductor layer is formed.

19. The manufacturing method of the semiconductor device according to claim 13, wherein the forming of the pillar member includes
forming the first block insulating film, the memory film, and the channel semiconductor layer in order in a conformal state on a side surface inside the memory hole, and
embedding a second insulating film into the memory hole covered with the channel semiconductor layer.

20. The manufacturing method of the semiconductor memory device according to claim 13, wherein, in the embedding of the electrode film, the electrode film is embedded into the gap provided with a barrier metal film formed on the second block insulating film.
